(19) United States
(12) Patent Application Publication
(10) Pub. No.: US 2025/0308952 A1
(43) Pub. Date: Oct. 2, 2025

(54) HIGH-EFFICIENCY LED SUBSTRATE HEATER FOR DEPOSITION APPLICATIONS

(71) Applicant: LAM RESEARCH CORPORATION, Fremont, CA (US)

(72) Inventors: Paul KONKOLA, West Linn, OR (US); Boaz KENANE, Portland, OR (US)

(21) Appl. No.: 18/881,980

(22) PCT Filed: Jun. 21, 2023
(86) PCT No.: PCT/US2023/025809

§ 371 Date: Jan. 7, 2025

Related U.S. Application Data
(60) Provisional application No. 63/388,704, filed on Jul. 13, 2022.

(51) Int. Cl. H01L 21/67; H01L 21/687; H05B 3/00; H10H 29/80

(52) U.S. Cl. CPC H01L 21/67115; H01L 21/68785; H01L 21/68792; H05B 3/0047; H10H 29/842; H01L 21/68742

(57) ABSTRACT

An optical array arranged in a pedestal configured to deposit material on a substrate includes a plurality of optical elements, a window, and an array of pinholes. The optical elements are arranged on a printed circuit board (PCB). The optical elements are configured to emit light. The window comprises an optically transparent material covering the optical elements arranged on the PCB. The array of pinholes is disposed between the optical elements and the window. The pinholes are vertically aligned with the optical elements to direct the light emitted by the optical elements through the window to heat the substrate.

### CROSS-REFERENCE TO RELATED APPLICATIONS

This application claims the benefit of U.S. Provisional Application No. 63/388,704, filed on Jul. 13, 2022. The entire disclosure of the above application is incorporated herein by reference.

### FIELD

The present disclosure relates generally to semiconductor processing systems and more particularly to a high-efficiency LED substrate heater for deposition applications.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of processing chambers (also called process modules) to perform deposition, etching, and other treatments of substrates such as semiconductor wafers. Examples of processes that may be performed on a substrate comprise chemical vapor deposition (CVD), plasma enhanced CVD (PECVD), chemically enhanced plasma vapor deposition (CEPVD), atomic layer deposition (ALD), epitaxial deposition, sub-atmospheric CVD, plasma enhanced ALD (PEALD), and multitude of other deposition processes that require to have the substrate at high temperature. Additional examples of processes that may be performed on a substrate comprise etching (e.g., chemical etching, plasma etching, reactive ion etching, etc.) and cleaning processes.

During processing, a substrate is arranged on a substrate support or a susceptor such as a pedestal, or a chuck (ESC), and so on in a processing chamber of the substrate processing system. In some processes, during deposition, gas mixtures comprising one or more precursors are introduced into the processing chamber, and plasma may be struck to activate chemical reactions. In other processes, during etching, gas mixtures comprising etch gases are introduced into the processing chamber, and plasma may be struck to activate chemical reactions. A computer-controlled robot is used to transfer substrates from one processing chamber to another in a sequence in which the substrates are to be processed.

### SUMMARY

An optical array arranged in a pedestal configured to deposit material on a substrate comprises a plurality of optical elements, a window, and an array of pinholes. The optical elements are arranged on a printed circuit board (PCB). The optical elements are configured to emit light. The window comprises an optically transparent material covering the optical elements arranged on the PCB. The array of pinholes is disposed between the optical elements and the window. The pinholes are vertically aligned with the optical elements to direct the light emitted by the optical elements through the window to heat the substrate.

In additional features, the optical array further comprising lenses disposed between the optical elements and the pinholes. The lenses are aligned with the optical elements and the pinholes to converge the light from the optical elements to the pinholes.

In additional features, the optical elements comprise lenses to converge the light from the optical elements to the pinholes.

In additional feature, the array of pinholes comprises a metallic or dielectric material.

In additional feature, the array of pinholes is integrated with the window in a monolithic assembly.

In additional feature, the array of pinholes is coated with a reflective material on a side facing the window. The reflective material does not cover the pinholes.

In additional feature, the array of pinholes is coated with an antireflective material on a side facing the optical elements.

In additional features, the window is coated with an antireflective material on a side facing the optical elements and a material that is antireflective for wavelengths of the light emitted by the optical elements and that is reflective for infrared wavelengths on a side facing the substrate.

In additional features, the window is coated with an antireflective material on a side facing the optical elements. The window further comprises a reflective material coated on the antireflective material. The reflective material comprises a metal film and the pinholes.

In additional features, the optical elements comprise light emitting diodes.

In additional features, the optical elements comprise light emitting diodes configured to emit light having wavelengths between 530 nm and 1000 nm.

In additional features, the optical array is circular. The optical elements and the pinholes are arranged in concentric circles from an inner diameter to an outer diameter of the optical array.

In additional features, the optical array further comprises lenses disposed between the optical elements and the pinholes. The optical array is circular. The optical elements, the pinholes, and the lenses are arranged in concentric circles from an inner diameter to an outer diameter of the optical array. The lenses are aligned with the optical elements and the pinholes to converge the light from the optical elements to the pinholes.

In additional features, the pinholes are cylindrical.

In additional features, the pinholes are conical with bases facing the optical elements.

In additional features, the PCB further comprises one or more driver circuits configured to control power supply to the optical elements.

In additional features, the PCB further comprises one or more driver circuits configured to control operation of selected ones of the optical elements.

In additional features, the PCB further comprises driver circuits configured to control the light emitted by the optical elements. The driver circuits are arranged on the same side of the PCB as the optical elements, on an opposite side of the PCB, or on both sides of the PCB.

In additional features, the optical array further comprises a heat sink attached to a side of the PCB opposite to a side on which the optical elements are arranged on the PCB.

In additional features, the window is sealingly attached to the PCB.

In additional features, a system comprises the optical array and the pedestal. The pedestal comprises a stem portion and a base portion mounted to the stem portion. The optical array is disposed in the base portion of the pedestal.

In additional features, the base portion and the optical array are coplanar.

In additional features, the base portion and the optical array are circular. An outer diameter of the optical array is less than or equal to an outer diameter of the base portion.

In additional features, the base portion and the optical array are circular. An outer diameter of the array is less than or equal to an outer diameter of the substrate.

In additional features, the base portion and the optical array are circular. An outer diameter of the array is at least equal to an outer diameter of the substrate.

In additional features, the pedestal further comprises a shaft and an actuator. The shaft is disposed through centers of the stem portion, the base portion, and the array. The actuator is coupled to the shaft and configured to move the substrate relative to the pedestal.

In additional features, the pedestal further comprises a shaft and an actuator. The shaft is disposed through centers of the stem portion, the base portion, and the array. The actuator is coupled to the shaft and configured to move the substrate perpendicularly relative to a plane in which the base portion lies.

In additional features, the pedestal further comprises a shaft and an actuator.

The shaft is disposed through centers of the stem portion, the base portion, and the array. The actuator is coupled to the shaft and configured to rotate the substrate relative to the base portion.

In additional features, the pedestal further comprises a shaft and an actuator. The shaft is disposed through centers of the stem portion, the base portion, and the array.

The shaft comprises a conduit to receive a gas and a plurality of holes in fluid communication with the conduit near a first end of the shaft proximate to the array. The actuator is coupled to a second end of the shaft and configured move the substrate perpendicularly relative to a plane in which the base portion lies. The plurality of holes supply the gas radially over the window when the shaft is raised above the array.

In additional feature, the array of pinholes is connected to a ground potential.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of an optical array used in a pedestal in a system shown in FIG. 1B to heat substrates according to the present disclosure;

FIG. 1B shows an example of a system for processing substrates according to the present disclosure;

FIG. 2 shows a plan view of an optical array used in a pedestal in the system of FIG. 1B to heat substrates according to the present disclosure;

FIG. 3 shows a cross-sectional view of the optical array of FIG. 2;

FIGS. 4A-4D show an example of the optical array of FIG. 2 in detail;

FIGS. 5A-5D show another example of the optical array of FIG. 2;

FIG. 6 shows a plan view of a pinhole array used in the optical array of FIG. 2:

FIG. 7 shows a plan view of lenses used in the optical array of FIG. 2;

FIG. 8 shows a block diagram of a system for controlling the optical array of FIG. 2 used in a pedestal in the system of FIG. 1B to heat substrates according to the present disclosure; and

FIGS. 9 and 10 show an example of a pedestal using vacuum clamping and comprising the optical array of FIG. 2 that can be used in the system of FIG. 1B to heat substrates according to the present disclosure.

In the drawings, reference numbers may be reused to identify similar and/or identical elements.

### DETAILED DESCRIPTION

Typically, resistively heated pedestals or susceptors are used for heating substrates in deposition applications. A pedestal comprises a thermally conductive body, usually fabricated from a metal such as aluminum, that monolithically houses a heater element that heats the thermally conductive body. The thermally conductive body spreads out heat flux to heat a substrate arranged on the pedestal during processing. Gas conduction combined with radiation between the substrate and the heated pedestal thermally couples the substrate to the pedestal.

Resistively heated pedestals have limited ability to tune or adjust localized heating of the substrate in a recipe-controllable manner because heating elements for localized heating are difficult to implement in the monolithic body of the pedestal. The ability to tune or adjust localized heating of the substrate is further limited because the thermally conductive body spreads out heat locally to enhance global temperature uniformity across the pedestal. In contrast, less thermally conductive materials such as ceramic struggle to balance sufficiently low thermal resistance to enable localized heating and sufficiently high fracture toughness and thermal shock resistance to prevent inadvertent fracture. Another limitation for heat uniformity across the substrate is the proximity to chamber walls and the radiative and conductive heat loss which is different at every part of the substrate which requires compensation in the form of different heating power by the heating body.

Instead, an optical array such as an LED array disposed in or on the pedestal can be used to heat substrates. Unlike other heating elements, the optical array comprises optical elements such as LEDs that can emit light to optically heat a substrate. The optical array can tune or adjust localized heating of the substrate in a recipe-controllable manner. While substrates can be heated by light of shorter wavelengths, photo-induced corrosion can occur at wavelengths below 530 nm. Accordingly, wavelengths for optical heating of substrates are selected preferably between 530 nm and 1000 nm. The optical array-based heating provides recipe-controlled, highly tunable substrate heating to adjust thermal uniformity, improve unit process, and compensate for upstream or downstream process issues.

In vacuum deposition applications, the optical array is encapsulated in a sealed housing. The light from the optical array shines through an optically transparent window, generally made of quartz or sapphire, onto the substrate. In some examples, the substrate and the optical array may be stationary relative to each other. Alternatively, the substrate and the optical array may rotate relative to each other.

The window needs to be maintained clean to prevent optical transmission efficiency of the window from drifting due to parasitic deposition on the surface of the window. For applications where the substrate rests directly onto the window, purging schemes such as edge purging through an annulus or an annular arrangement of gas purge apertures can be used to maintain the window clean. Alternatively, if the substrate is separated off the window and process pressure is above a threshold (e.g., at least 40 Torr or so), a cross flow gas purging arrangement utilizing Coanda effect can be used. Alternatively, the window may be subjected to periodic dry chemical cleaning. These features may also be utilized in aqueous (wet) deposition applications.

From an environmental, social, and governance (ESG) perspective, LEDs perform better than other heating elements. LED heating may be less efficient from electrical power to thermal power conversion perspective. However, due to the low temperature of the LEDs, LED heating can prevent radiative loss to the rest of the processing chamber. Specifically, due to directed heating provided by the LEDs, the optical array heats only the substrate and not the processing chamber. Further, LED heating can also provide zonal heating control for thermal-only, non-plasma applications. Therefore, LED heating provides a more efficient wafer heating system than other forms of heating.

Typically, the optical array-based heater converts about ⅓-½ of electrical power supplied to the LEDs into optical power. Of the optical power, about 60% heats the substrate, and 40% is reflected back from the substrate. The reflected power heats the LED PCB, a metal core PCB that supplies the electrical power to the LED PCB, and a heat sink disposed under the metal core PCB. The LED PCB is typically coated with a white paint to reduce heat absorption. However, the surface area occupied by the LEDs and their associated electrical contact pads is significant as compared to the total surface area of the LED PCB. Moreover, a portion of the wasted heat heats the electronics on the metal core PCB that supplies the electrical power to the LED PCB and sets an upper limit on usable operating substrate temperature during processing. To overcome the limitation, the optical heating efficiency of the optical array-based heater needs to be increased. The present disclosure provides a system to minimize the optical power absorbed by the LED PCB and maximize the optical power available to heat the substrate.

Specifically, a pinhole array comprising small apertures is disposed above the LED array. The pinhole array can be made of a metallic or dielectric material (e.g., glass coated with a dielectric material). A focusing layer is disposed between the LED array and the pinhole array to focus the light from the LEDs through the small apertures in the pinhole array. For example, the focusing layer may comprise an array of converging lenses manufactured as a single assembly using printing or other fabricating methods. Alternatively, the LED array may be manufactured such that each LED comprises an inbuilt lens.

The pinhole array is coated with an ultra-reflective coating (e.g., barium sulfate, dielectric thin films, or metal and dielectric thin films) on a side opposite to the LEDs (i.e., the side facing the substrate). The ultra-reflective coating does not cover the pinholes themselves but covers the rest of the surface area of pinhole array. Optionally, an antireflective coating may also be applied to the pinhole array on a side facing the LEDs. Due to these coatings, the pinhole array transfers maximum optical power from the LEDs through the window to the heat the substrate.

In addition, the window disposed above the LED array may be coated by a suitable coating that reduces the amount of light reflected back through the window and that reduces infrared heat transfer from the substrate to the LED array. Specifically, a first coating applied on a substrate-facing side (i.e., a wafer-facing side) of the window reflects secondary light reflected from a bottom surface of the substrate back to the bottom surface of the substrate. Thus, the first coating improves the optical heating efficiency of the LED array. The first coating can be antireflective at wavelengths of light emitted by the LEDs to pass the light from the pinhole array to the substrate (i.e., the wafer). Additionally, the first coating can be reflective at infrared wavelengths to reduce infrared heat transfer from the substrate to the LED array. A second antireflective coating is preferably also applied to a LED-facing side of the window to pass maximum light from the pinhole array through the window to heat the substrate (i.e., the wafer). The second coating can also be reflective at infrared wavelengths to reduce infrared heat transfer from the substrate to the LED array.

Alternatively, the pinhole array need not be a separate element. Rather, a layer of a reflective coating can be applied on the antireflective coating on the LED-facing side of the window to provide pinholes in the layer of the reflective coating itself. That is, the pinholes can be provided in the layer of the reflective coating itself. Accordingly, the window with antireflective coatings on top and bottom surfaces and with the layer of the reflective coating providing the pinholes can be manufactured as a monolithic assembly instead of the window and the pinhole array being two separate components.

In the monolithic assembly, the antireflective coating between the reflective coating and the window is formed by a blanket coating process (e.g., a blanket deposition of a film). However, the antireflective coating acts as a reflective coating in the presence of the reflective coating underneath the antireflective coating. The antireflective layer is designed such that the antireflective layer will nominally let all the light pass at the pinhole with no reflection. A reflective coating comprising a metal layer has little influence from a coating underneath the metal layer, for instance, since the skin depth of the metal is small compared to the thickness of the metal.

If dielectric films are used to form the reflective layer, the antireflective layer can interact with the reflective layer in a way that can complicate the film design since all the dielectric layers of the antireflective and reflective need to be considered. Instead, when a metal film is used in the reflective layer, the electromagnetic field of the light cannot pass through the metal film, and the light cannot interact with the antireflective layer, which simplifies the design of the metal film. Any material used below the metal film to form the reflective layer (and the pinholes) does not affect the functions of the reflective and antireflective layers since the metal film in the reflective layer is thick enough (i.e., much thicker than the skin depth of the metal). When the metal film is much thicker than the skin depth. the metal film makes the antireflective coating invisible to the light. Such functionality cannot be achieved if the reflective layer is made of a dielectric film.

The net effect of the system is to significantly increase optical power provided by the LED array to the substrate by repurposing the secondary light reflected by the substrate to heat the substrate and by reducing heat transfer from the substrate to the LED array. The reflective pinhole array significantly increases the surface area of the reflective surface of the pinhole array to much greater than 90% and reduces the optical power that goes into heating the electronics powering the LEDs. Thus, the system increases the usable operating temperature of the optical array-based heater across a wide variety of processes used to process the substrate and reduces the losses to the heatsink.

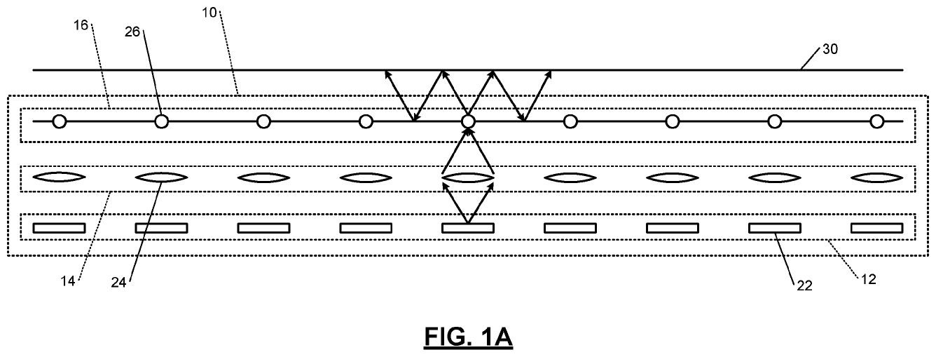

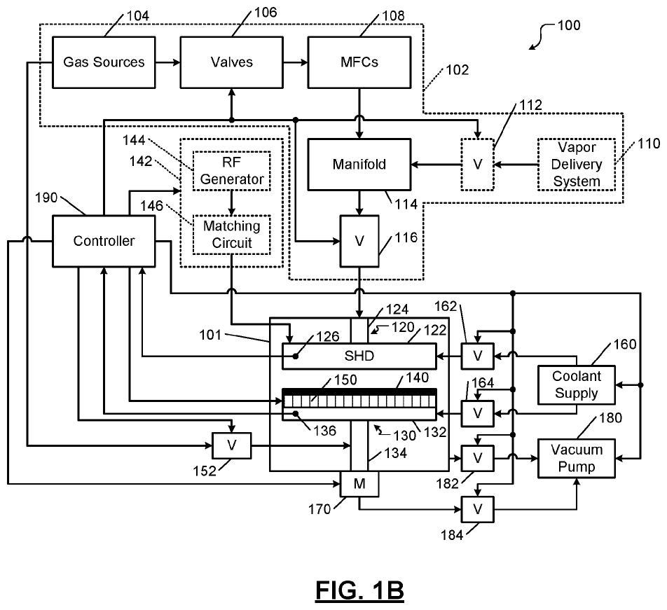

FIG. 1A shows an example of an optical array 10 according to the present disclosure. The optical array 10 comprises an LED array 12, a lens array 14, a pinhole array 16. The LED array 12 comprises a plurality LEDs 22. The lens array 14 comprises a plurality of lenses 24. The pinhole array 16 comprises a plurality pinholes 26. The LEDs 22, the lenses 24, and the pinholes 26 are vertically aligned with each other. As described below in detail with reference to FIGS. 2-7, the LEDs 22 are arranged on a metal core PCB, and a transparent window is arranged above the pinhole array 16. A substrate 30 is placed above the optical array 10 (i.e., above the window).

As shown by arrows, the light from each LED 22 is concentrated by a corresponding lens 24 through a corresponding pinhole 26 and onto the substrate 30. Some of light incident on the substrate 30 is absorbed by the substrate 30 and is used to heat the substrate 30. A large portion of the light incident on the substrate 30 is typically reflected back from the bottom of the substrate 30. However, the light reflected back from the substrate 30 cannot pass through the surface of the pinhole array 16 and is instead reflected back onto the bottom of the substrate 30 where again another portion of this light is absorbed by the substrate 30, and so on. In order to enhance this effect, the surface of the pinhole array 16 facing the substrate 30 is coated with a reflective coating for wavelengths that are best absorbed by the surface. Thus, the heating efficiency of the optical array 10 is improved. These and other features of the present disclosure are described below in detail. The optical array 10 is shown and described as optical array 150 in further detail with reference to FIGS. 1B-10.

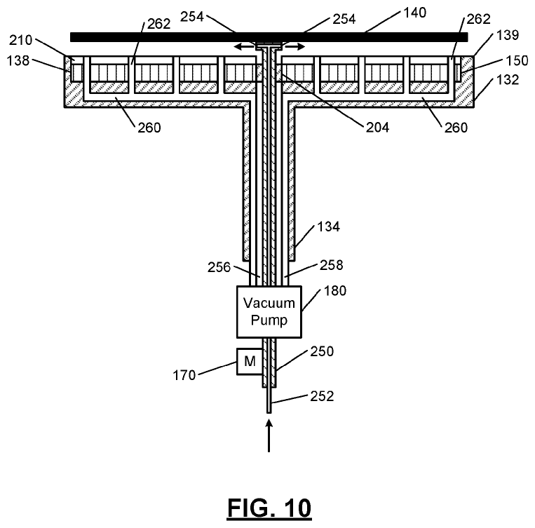

The remainder of the present disclosure is organized as follows. In Section 1, an example of a system for processing substrates according to the present disclosure is shown and described with reference to FIG. 1B. The system provides an example of an environment in which the optical array and the pedestal shown and described with reference to FIGS. 2-10 can be implemented. In Section 2, examples of the optical array used in a pedestal in the system of FIG. 1B to heat substrates is shown and described with reference to FIGS. 2-8. In Section 3, an example of a pedestal using vacuum clamping and comprising the optical array used in the system of FIG. 1B to heat the substrates is shown and described with reference to FIGS. 9 and 10.

### Section 1: Example of Substrate Processing System

FIG. 1B shows an example of a substrate processing system (hereinafter the system 100). The system 100 can be used to process substrates using chemical vapor deposition (CVD), plasma enhanced CVD (PECVD), chemically enhanced plasma vapor deposition (CEPVD), atomic layer deposition (ALD), or plasma enhanced ALD (PEALD) processes.

The system 100 comprises a processing chamber 101 and a gas distribution system 102. The gas distribution system 102 comprises a plurality of gas sources 104, a plurality of valves 106 connected to the gas sources 104, a plurality of mass flow controllers (MFCs) 108 connected to the valves 106. The gas sources 104 supply various gases comprising process gases, precursors, purge gases, inert gases, cleaning gases, and so on. The MFCs 108 control the mass flow rates of the gases.

In some applications, the gas distribution system 102 further comprises a vapor delivery system 110 to supply one or more vaporized precursors through one or more valves 112. One or more gases from the MFCs 108 and, when used, one or more vaporized precursors are supplied to a mixing manifold 114. The gases or gas mixtures from the mixing manifold 114 are supplied to the processing chamber 101 through a valve assembly (e.g., a pulsed valve manifold or PVM assembly) 116.

The processing chamber 101 comprises a showerhead 120 and a pedestal 130. The showerhead 120 is attached to a top plate of the processing chamber 101. The showerhead 120 receives the gases or gas mixtures from the mixing manifold 114 through the valve assembly 116. The showerhead 120 comprises a base portion 122 and a stem portion 124. The stem portion 124 extends from the center of the base portion 122 and is attached to the top plate of the processing chamber 101. The base portion 122 is cylindrical and comprises a plurality of through holes (not shown) through which the gases or gas mixtures are supplied into the processing chamber 101.

The pedestal 130 comprises a base portion 132 and a stem portion 134. The stem portion 134 is generally cylindrical or can be Y-shaped, with the tapered (i.e., the top of the Y) portion attached to a bottom of the base portion 132. The stem portion 134 extends from the base portion 132 and is attached to the bottom of the processing chamber 101. The base portion 132 is also cylindrical. A substrate 140 is arranged on a top surface of the base portion 132 of the pedestal 130 during processing.

While not shown, the base portion 132 of the pedestal 130 may comprise lift pins to hold, lower. and raise the substrate 140 relative to the base portion 132 of the pedestal 130. Optionally, a shaft (shown and described below) extending through the stem portion 132 and the base portion 132 of the pedestal 130 may be used to hold, lower, and raise the substrate 140 relative to the base portion 132 of the pedestal 130. The lift pins and the shaft can be used in combination to hold, lower, and raise the substrate 140 relative to the base portion 132 of the pedestal 130.

The substrate 140 may be clamped to the base portion 132 using one of many clamping schemes. Examples of the clamping schemes comprise vacuum clamping, electrostatic clamping, and mechanical clamping. An example of the pedestal 130 comprising vacuum clamping, which can be used in the processing chamber 101, is shown and described below with reference to FIGS. 9 and 10.

The base portion 132 comprises an optical array (e.g., an LED array) 150 to heat the substrate 140 as shown and described below in detail. The optical array 150 comprises optical elements (e.g., LEDs), lenses, a pinhole array. and a transparent window (all shown and described below with reference to FIGS. 2-8). The LEDs emit light having wavelengths selected preferably between 530 nm and 1000 nm for optical heating of the substrate 140. Through the transparent window, the light from the LEDs, the lenses, and the pinhole array in the optical array 150 is incident on a bottom surface of the substrate 140 to heat the substrate 140.

The substrate 140 may be heated while being held above the optical array 150 (e.g., by lift pins that pass through the optical array 150 or by the shaft). The substrate 140 may be heated when the substrate 140 rests on the optical array 150 without being clamped. The substrate 140 may be heated when the substrate 140 rests on the optical array 150 upon being clamped to the pedestal 130 using any of the clamping methods mentioned above.

A purge gas (e.g., an inert gas) from one of the gas sources 104 is supplied through a valve 152 to the stem portion 134. The purge gas flows radially over and across the window of the optical array 150 to clean the window and maintain the transparency of the window as explained below in detail. An example of the pedestal 130 comprising the optical array 150 and a purging mechanism, which can be used in the processing chamber 101, is shown and described below in detail with reference to FIGS. 9 and 10.

In some applications (e.g., in PECVD and PEALD processes), plasma may be used to process the substrate 140. The system 100 comprises a radio frequency (RF) system 142 used to generate plasma in the processing chamber 101. The RF system 142 comprises a RF generator 144 and a matching circuit 146. The RF system 142 supplies RF power to the showerhead 120 while the pedestal 130 is grounded. Alternatively, while not shown, the RF power can be supplied to the pedestal 130 while the showerhead 120 is grounded. The RF power activates the gases or gas mixtures supplied through the showerhead 120 and generates plasma between the showerhead 120 and the substrate 140 arranged on the pedestal 130.

The showerhead 120 and the pedestal 130 comprise temperature sensors 126, 136 to sense the temperatures of the showerhead 120 and the pedestal 130. The showerhead 120 and the pedestal 130 comprise cooling channels (now shown). A coolant is circulated through the cooling channels to control the temperatures of the showerhead 120 and the pedestal 130. A coolant supply 160 may supply the coolant to the cooling channels in the showerhead 120 and the pedestal 130 via valves 162, 164.

One or more actuators generally shown at 170 may be used to move the pedestal 130 relative to the showerhead 120. One of the actuators 170 may also be used to move and rotate a shaft (shown in FIGS. 9 and 10) that passes through the stem portion 134 of the pedestal 130 to lift and rotate the substrate 140. The purge gas used to clean the window of the optical array 150 is supplied through the valve 152 via a conduit in the shaft as shown and described below with reference to FIGS. 9 and 10.

A vacuum pump 180 is connected to the bottom of the processing chamber 101 through a valve 182. The vacuum pump 180 is used to maintain vacuum in the processing chamber 101 and to evacuate reactants and process byproducts from the processing chamber 101. Additionally, when vacuum clamping is used, the vacuum pump 180 is connected to the stem portion 134 of the pedestal 130 through a valve 184. The vacuum pump 180 maintains vacuum through an annular volume around the shaft in the stem portion 134 of the pedestal 130 (shown and described below) to clamp the substrate 140 to the pedestal 130.

In addition, the stem portion 134 comprises a conduit (shown in FIGS. 9 and 10) through which electrical connections are provided to various electrical elements disposed in the base portion 132 of the pedestal 130. For example, the electrical elements comprise the optical array 150, the temperature sensors 126, 136, and other electrical elements (e.g., clamping electrodes when the pedestal 130 comprises an electrostatic chuck) disposed in the base portion 132 of the pedestal 130.

A controller 190 controls the various elements of the system 100 (e.g., the gas distribution system 102, the valves, the RF system 142, the optical array 150. the coolant supply 160, the actuators 170, the vacuum pump 180, etc.). The controller 190 receives data from the temperature sensors 126, 136 and controls the temperatures of the showerhead 120 and the pedestal 130 by controlling the optical array 150 and the coolant supply 160. These and other features of the system 100 are described below in further detail.

### Section 2: Optical Array

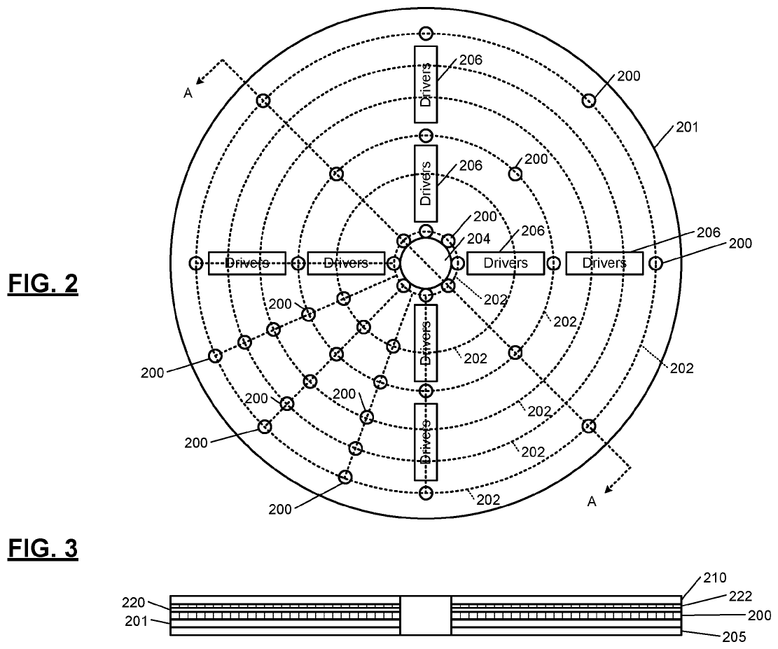

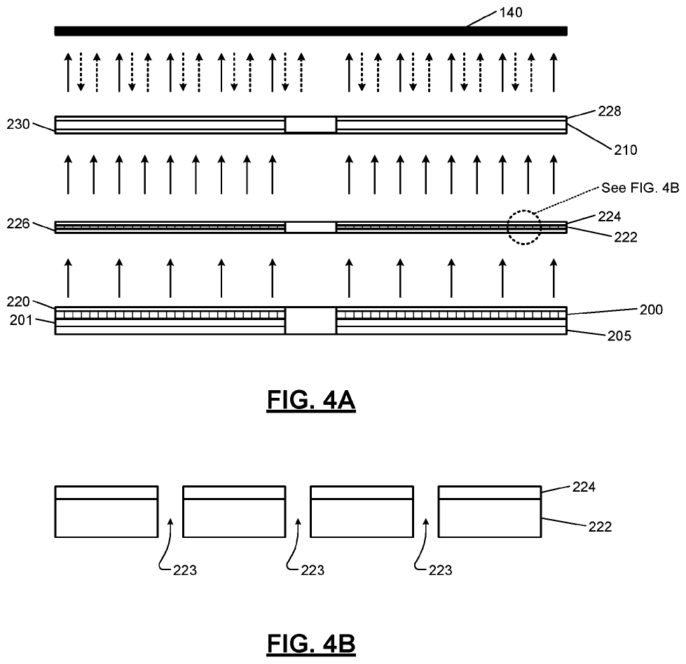

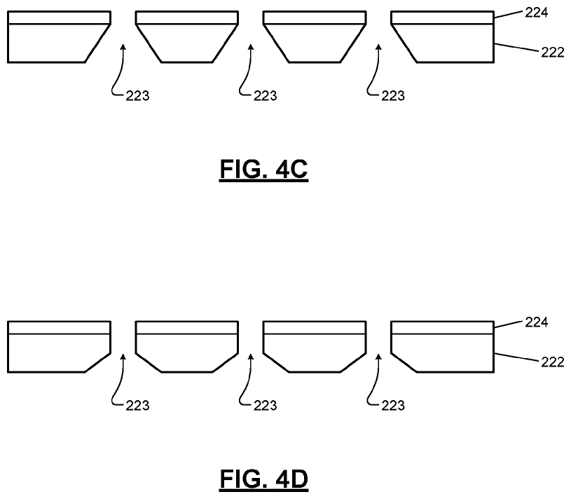

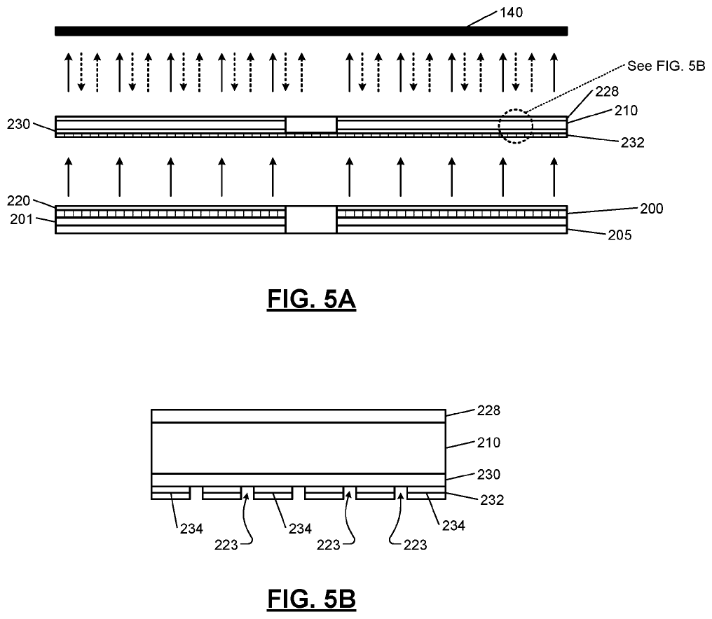

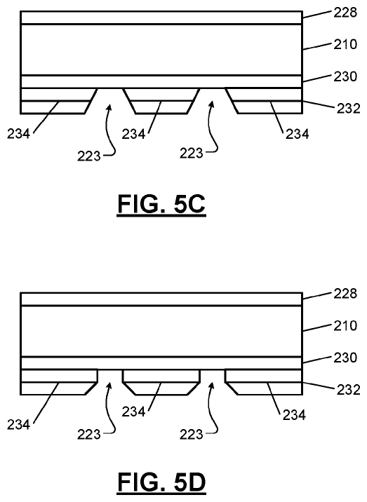

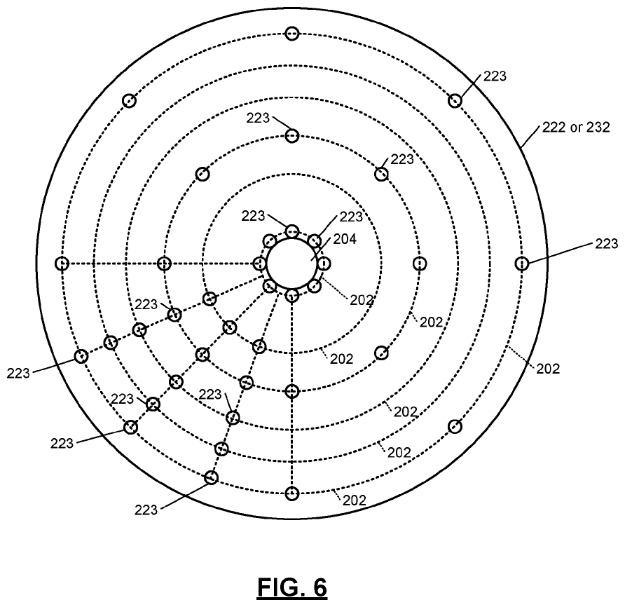

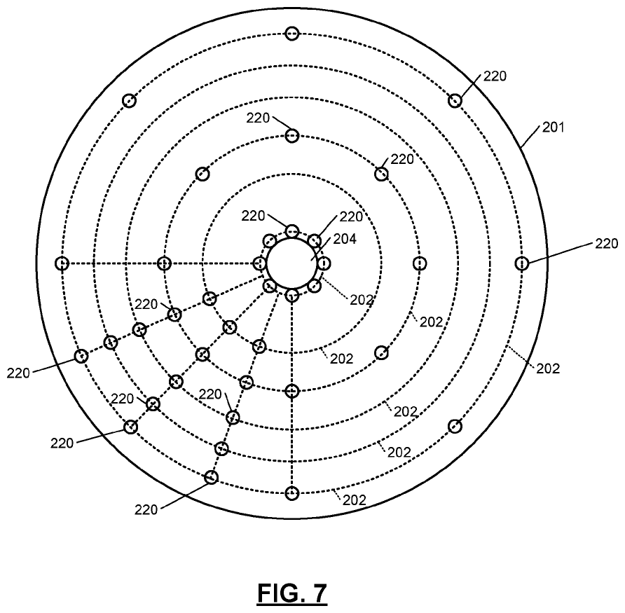

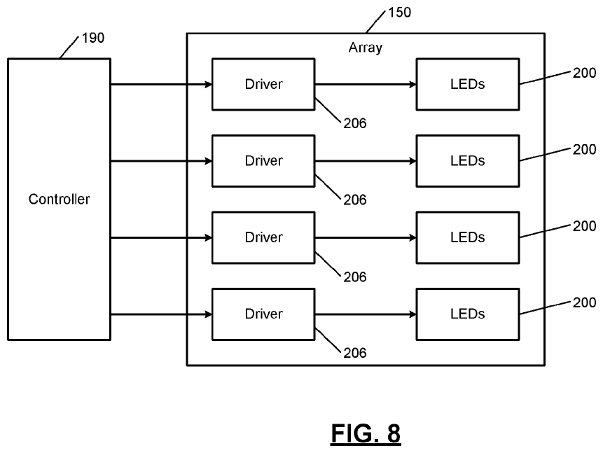

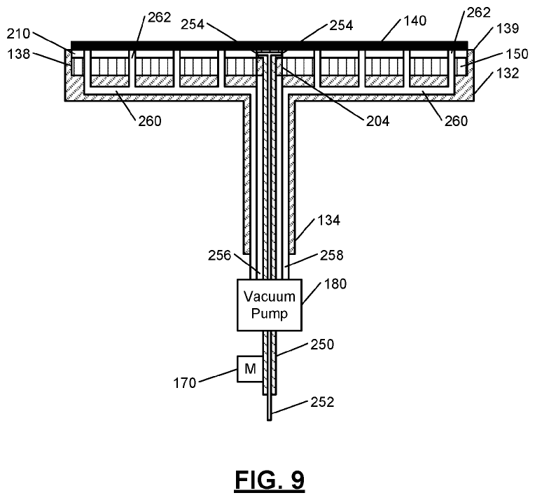

FIGS. 2-8 show various examples of the optical array 150. FIG. 2 shows a top view of the optical array 150. FIG. 3 shows a cross-sectional view of the optical array 150 taken along line A-A shown in FIG. 2. FIGS. 4A-4D show a first example (implementation) of the optical array 150 in which a pinhole array is implemented as a separate element. FIGS. 5A-5D show a second example (implementation) of the optical array 150 in which the pinhole array is integrated with the window (i.e., the window and the pinhole array are a monolithic assembly). FIG. 6 shows a top view of the pinhole array, showing pinholes being coincident with the LEDs. FIG. 7 shows a top view of the lens array, showing lenses being coincident with the LEDs. FIG. 8 shows a block diagram of the circuitry that controls the optical array 150. FIGS. 2-8 are now described below in detail.

In FIG. 2, the optical array 150 is generally circular and has a radius that is less than an outer diameter (OD) of the base portion 132 of the pedestal 130. The radius of the optical array 150 is approximately equal or at least equal to a radius of the substrate 140. For example, the optical array 150 comprises a plurality of LEDs 200 arranged on a printed circuit board (PCB) 201. The PCB 201 may be a metal core PCB. For example, the LEDs 200 are arranged on the PCB 201 in concentric circles 202. While only a few concentric circles 202 are shown for illustrative purposes, the number of the concentric circles 202 may vary. For example, the concentric circles 202 may be denser than those shown. Further, the number of LEDs 200 in each concentric circle 202 may be more than that shown. Accordingly, the concentric circles 202 and the LEDs 200 are more densely arranged in the optical array 150 than shown. The concentric circles 202 and the LEDs 200 extend from an inner annular region 204 of the optical array 150 up to an OD of the optical array 150. The LEDs 200 emit light having wavelengths selected preferably between 530 nm and 1000 nm for optical heating of the substrate 140. The light emitted by the LEDs 200 optically heats the substrate 140.

The LEDs 200 may be arranged in the concentric circles 202 in different patterns. For example, the LEDs 200 in some of the concentric circles 202 may be arranged more densely than in other concentric circles 202. For example, the LEDs 200 in some portions (e.g., zones or quadrants) of the optical array 150 may be arranged more densely than in other portions of the optical array 150. Further, the size, luminosity, and/or wavelength(s) of the LEDs 200 may vary from one concentric circle 202 or portion to another. Any combinations of these and additional features of the LEDs 200 may be used in the optical array 150.

The optical array 150 comprises one or more driver circuits (hereinafter the drivers) 206 arranged on the PCB 201. While multiple drivers 206 are shown, a single driver 206 may be used. The following description of the drivers 206 applies to the single driver when used. The drivers 206 control the LEDs 200 as described below in detail. For example, the drivers 206 may be arranged on the PCB 201 on the same side as the LEDs 200, on the opposite side of the PCB 201, or on both sides of the PCB 201. For example, one or more of the drivers 206 may be arranged along different radii on the PCB 201. For example, the drivers 206 may be arranged in a regular pattern or in an irregular pattern (e.g., randomly) on the PCB 201. The drivers 206 are described in further detail with reference to FIG. 8 below.

In FIG. 3, the optical array 150 further comprises a window 210, lenses (e.g., convex lenses) 220, and a pinhole array 222. The lenses 220 are arranged above the LEDs 200. For example, the lenses 220 may be in the form of a lens array (show in FIG. 7) that can be disposed on top of the LEDs 200. As shown in FIG. 7, the lenses 220 in the lens array are also arranged in the concentric circles 202 so that the lenses 220 align or coincide with the LEDs 200. Alternatively, the lenses 220 may be integrated within the LEDs 200. That is, each LED may comprise a lens. In either implementation, the lenses 220 converge (i.e., focus) the light emitted by the LEDs onto the pinholes in the pinhole array 222.

The pinhole array 222 can be implemented as a separate element as shown and described below with reference to FIGS. 4A-4D. In an alternate design, the pinhole array 222 can be integrated into the window 210 as a monolithic assembly as shown and described below with reference to FIGS. 5A-5D. When used as a separate element, the pinhole array 222 is made of a metallic or dielectric material (e.g., glass coated with a dielectric material). As shown in FIG. 6, multiple holes are drilled through the pinhole array 222. Similar to the lenses 220, the holes are drilled in the pinhole array 222 in the concentric circles 202 so that the holes also align or coincide with the LEDs 200. Accordingly, the LEDs 200, the lenses 220, and the holes (i.e., pinholes 223 shown in FIGS. 4A-5B) in the pinhole array 222 are vertically aligned with each other. The lenses 220 and the holes in the pinhole array 222 provide a straight path for the light from the LEDs 200 to the window above the optical array 150 and through the window to the substrate 140 (shown in FIGS. 1, 9, and 10). The alternate design is described with reference to FIGS. 5A-5D.

In either implementation, the window 210 comprises an optically transparent, chemically resistant, and electrically insulating material such as quartz or sapphire. The window 210 comprises an opening in the center region that coincides with an inner annular region 204 of the optical array 150. The opening has a diameter that matches the diameter of the inner annular region 204 of the optical array 150. The inner and outer peripheries of the window 210 are sealingly attached to the inner and outer peripheries of the optical array 150, respectively. Accordingly, the optical array 150 and the window 210 form a sealed enclosure in which the LEDs 200, the PCB 201, the lenses 220, and the pinhole array 222 are housed. A heat sink 205 is attached to a bottom surface of the PCB 201. The heat sink 205 removes heat from the PCB 201.

FIGS. 4A-4D show the first example of the optical array 150 in further detail. In FIG. 4A, the pinhole array 222 is implemented as a separate element. The pinhole array 222 comprises pinholes 223 drilled through the pinhole array 222 as described above. When the substrate of the pinhole array 222 is thin, the pinholes 223 may be straight through as shown in FIGS. 4A and 4B. Alternatively, when the substrate thickness is significant or sufficient, the pinholes 223 may have a countersunk shape that substantially accounts for the convergence angle of the focused light. Two non-limiting examples of the pinholes 223 with the countersunk shape are shown in FIGS. 4C and 4D. While the pinholes 223 are shown generally circular, cylindrical, and conical, the pinholes 223 can have other shapes.

The pinhole array 222 further comprises a first coating 224 that is applied on a first side opposite to the LEDs 200 (i.e., the side facing the substrate 140). For example, the first coating 224 comprises an optically ultra-reflective material (e.g., barium sulfate, dielectric thin films, or metal and dielectric thin films). The first coating 224 does not cover the pinholes 223 in the pinhole array 222 but covers the rest of the surface area of pinhole array 222 as shown in FIG. 4B. Optionally, a second coating 226 comprising an antireflective material may also be applied to the pinhole array 222 on a second side facing the LEDs 200. Due to these coatings 224, 226, the pinhole array 222 transfers maximum optical power from the LEDs 200 through the window 210 to the heat the substrate 140.

In addition, the window 210 may be coated by a suitable coating that reduces the amount of light reflected back through the window and that reduces infrared heat transfer from the substrate to the LED array. Specifically, a first coating 228 is applied on a side facing the substrate 140. The first coating 228 reflects secondary light reflected from a bottom surface of the substrate 140 back to the bottom surface of the substrate 140 as shown by dotted arrows. Thus, the first coating 228 improves the optical heating efficiency of the LED array.

The first coating 228 can be antireflective at wavelengths of light emitted by the LEDs 200 to pass the light from the pinhole array 222 to the substrate 140. Additionally, the first coating 228 can be reflective at infrared wavelengths to reduce infrared heat transfer from the substrate 140 to the optical array 150. A second coating 230 comprising an antireflective material is preferably also applied on a side facing the LEDs 200. The second coating 230 passes maximum light from the pinhole array 222 through the window 210 to heat the substrate 140. The second coating 230 can also be reflective at infrared wavelengths to reduce infrared heat transfer from the substrate 140 to the optical array 150.

FIGS. 5A-5D show the second example of the optical array 150 comprising the alternate design for the pinhole array 222. In the alternate design, the pinhole array 222 is not a separate element. Rather, a layer of a reflective coating 232 is applied on the second coating 230 on the LED-facing side of the window 210 to provide the pinholes 223 in the layer of the reflective coating 232 itself. That is, the pinholes 223 are provided in the layer of the reflective coating 232 itself as shown in FIG. 5B to form the pinhole array 222. Similar to the pinholes 223 in the pinhole array 222 shown and described above with reference to FIGS. 4A and 4B, the pinholes 223 in the layer of the reflective coating 232 are also arranged in the concentric circles 202. Thus, the window 210 with the antireflective coatings on top and bottom surfaces (i.e., the first and second coatings 228, 230) and with the layer of the reflective coating 232 comprising the pinholes 223 are manufactured as a monolithic assembly. Further, as shown in FIGS. 5C and 5D, the pinholes 223 shown in FIGS. 5A and 5B can also be shaped similar to the pinholes 223 in the pinhole array 222 shown and described above with reference to FIGS. 4C and 4D.

In the monolithic assembly, the antireflective coating (i.e., the second coating 230) between the reflective coating 232 and the window 210 is formed by a blanket coating process (e.g., a blanket deposition of a film). However, the antireflective coating (i.e., the second coating 230) acts as a reflective coating in the presence of the reflective coating 232 underneath the antireflective coating. The antireflective coating (i.e., the second coating 230) is designed such that the antireflective coating (i.e., the second coating 230) nominally allows all the light pass at the pinholes 223 with no reflection. The reflective coating 232, which comprises a metal film 234, has little influence from any other coating that may be underneath the metal film 234, for instance, since the skin depth of the metal in the metal film 234 is less than the thickness of the metal 234.

Since the metal film 234 is used in the reflective coating 232, the electromagnetic field of the light cannot pass through the metal film 234, and the light cannot interact with the antireflective layer (i.e., the second coating 230). Any material used below the metal film 234 to form the reflective coating 232 (and the pinholes 223) does not affect the functions of the reflective coating 232 and the antireflective layer (i.e., the second coating 230) since the metal film 234 in the reflective coating 232 is thick enough (i.e., much thicker than the skin depth of the metal in the metal film 234). When the metal film 234 is much thicker than the skin depth of the metal in the metal film 234, the metal film 234 makes the antireflective coating (i.e., the second coating 230) invisible to the light.

The coating materials described above comprise dielectric films with alternating low and high index of refraction. Examples of the coating materials used for the coatings described above comprise MgF2, TiO2, Ta2O5, Al2O3, ZrO2, SiO2. Thicknesses of the coatings are selected to maximize antireflection or reflection performance. For example, for a single film of coating, a thickness of λ/4 can be used for antireflection (destructive interference) and a thickness of λ/2 can be used for reflection (constructive interference), where λ is the wavelength of light emitted by the LEDs 200. Other design considerations comprise the wavelength range and the angle of incidence of the light.

FIG. 6 shows a top view of the pinhole array 222. The view shown is the same whether the pinhole array 222 is implemented as a separate element as shown in FIGS. 4A and 4B or is monolithic (i.e., integrated with the window 210 as a single assembly) as shown in FIGS. 5A and 5B. As described above, the pinholes 223 are arranged in the same concentric circles 202 as the LEDs 200. Accordingly, regardless of the implementation of the pinhole array 222, the pinholes 223, the lenses 220, and the LEDs 200 are vertically aligned with each other as described above.

FIG. 7 shows a top view of the lenses 220. The view shown is the same whether the lenses 220 are implemented in the form of the lens array (i.e., as a separate element) or are integrated into the LEDs 200 as described above. Further, as described above, the lenses 220 are arranged in the same concentric circles 202 as the LEDs 200. Accordingly, regardless of the implementation of the lenses 220, the pinholes 223, the lenses 220, and the LEDs 200 are vertically aligned with each other as described above. Specifically, each lens 220 is vertically aligned with a corresponding LED 200, and each pinhole 223 is vertically aligned with a corresponding lens 220 and a corresponding LED 200. Thus, the pinholes 223, the lenses 220, and the LEDs are collinear and provide a straight path for light from the LEDs 200, through the lenses 220, the pinholes 223, and the window 210 to the substrate 140.

FIG. 8 shows the circuitry to control the LEDs 200. Each driver 206 may control a set (group) of LEDs 200. The controller 190 may control the LEDs 200 by controlling the drivers 206. For example, after the substrate 140 is loaded into the processing chamber 101, the drivers 206 may supply power to the LEDs 200 at a first power level to preheat the substrate 140 while the substrate 140 is held above the pedestal 130 before the substrate 140 is lowered onto the pedestal 130 for depositing a film on the substrate 140. Subsequently, after a predetermined amount of time for which the substrate 140 is preheated, the drivers 206 may supply a reduced amount of power to the LEDs 200 at a second power level to heat the substrate 140 before or after the substrate 140 is lowered onto the pedestal 130. Subsequently, after the film is deposited on the substrate 140, the drivers 206 may supply a reduced amount of power to the LEDs 200 at a third power level before the substrate 140 is lifted off the pedestal 130 and removed from the processing chamber 101.

Additionally, in any of the steps described above, the drivers 206 may further control the power supplied to the LEDs 200. For example, each driver 206 may control a duty cycle (on/off times) of the respective LEDs 200. For example, each driver 206 may control the intensity (brightness) of the respective LEDs 200. For example, the controller 190 may control the drivers 206 such that only LEDs in selected concentric circles 202 or portions thereof are turned on or off at different times. For example, the controller 190 may control the drivers 206 such that only one or more LEDs 200 in a set (e.g., a zone or portion of the optical array 150) are turned on or off at different times. For example, the controller 190 may control the drivers 206 such that the LEDs 200 or different portions of the LEDs 200 can output varying amounts of light (i.e., optical heating power) at different times. The drivers 206 may control the power supplied to the LEDs 200 gradually or in steps. Any combination of these and additional controls may be used to control the LEDs 200.

In some examples, a portion or the entirety of the control provided by the controller 190 may be offloaded (in the form of hardware, firmware, or a combination thereof) into one or more drivers 206. In some examples, one or more drivers 206 may control the remaining drivers 206. In addition, the substrate 140 can be rotated relative to the optical array 150 as described below. The controller 190 and/or the drivers 206 can control the LEDs 200 differently before and after the substrate 140 is rotated. Thus, optical heating of different portions of the substrate 140 can be controlled by controlling one or more LEDs 200.

When used in the pedestal 130 shown in FIG. 1B, the optical array 150 and the window 210 can comprise any implementation of the lenses 220 and the pinholes 223 described above with reference to FIGS. 2-7. For example, the optical array 150 can comprise the lenses 220 in the form the lens array or the lenses 220 integrated with the LEDs 200. For example, the optical array 150 can comprise the pinholes array 222 implemented as a separate element or as a monolithic assembly (i.e., integrated with the window 210). Further, any combination of these implementations of the lenses 220 and the pinholes 223 may be used.

The pinhole array 222, when made of a metallic material and implemented as a separate element or when made of the reflective coating 232 comprising the metal film 234, can also function as a Faraday shield. Specifically, the pinhole array 222 can prevent electromagnetic interference from the light emitted by the LEDs 200 with the RF system 142 used to generate plasma in the processing chamber 101. To prevent the interference, when implemented in the pedestal 130 as shown in FIGS. 9 and 10, the pinhole array 222 can be grounded (i.e., connected to a ground potential).

### Section 3: Vaccum Clamping

FIGS. 9 and 10 show an example of the optical array 150 implemented in the pedestal 130 when vacuum clamping is used to clamp the substrate 140 to the pedestal 130. In addition, along with vacuum clamping, these figures show a purging mechanism used to maintain the window 210 clean and a rotation mechanism used to rotate the substrate 140 relative to the optical array 150. FIG. 9 shows an example of vacuum clamping. FIG. 10 shows the purging of the window 210 when the substrate 140 is lifted from the pedestal 130 and is rotated. Alternatively, while not shown, any other clamping scheme (e.g., electrostatic clamping and mechanical clamping) may be used to clamp the substrate 140 to the pedestal 130 comprising the optical array 150.

In FIG. 9, the optical array 150 along with the window 210 is disposed in an annular cavity 138 formed in the base portion 132 of the pedestal 130. The annular cavity 138 is formed by removing material from the top surface of the base portion 132 of the pedestal 130 except from a center region of the top surface of the base portion 132 of the pedestal 130. A depth of the annular cavity 138 is equal to a height of the optical array 150 and the window 210. The optical array 150 and the base portion 132 of the pedestal 130 are coplanar. Accordingly, a top surface of the window 210 is level with a top edge 139 of the base portion 132 of the pedestal 130. The substrate 140 is arranged on the top surface of the window 210 during processing. Vacuum clamping described below is used to clamp the substrate 140 to the pedestal 130.

The stem portion 134 of the pedestal 130 comprises a shaft 250. The shaft 250 extends through the centers of the stem portion 134 and the base portion 132 of the pedestal 130. The shaft 250 comprises a T-shaped end (i.e., the horizontal portion that forms the top of the T shape) and a distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. A top surface of the T-shaped end of the shaft 250 is level with top surface of the window 210. A bottom surface of the T-shaped end of the shaft 250 is level with and rests on top of the center region of the top surface of the base portion 132 of the pedestal 130. A diameter of the T-shaped end of the shaft 250 is slightly less than the diameter of the inner annular region 204 of the optical array 150 and the opening of the window 210.

The distal end of the shaft 250 extends through the bottom end of the stem portion 134 of the pedestal 130. The distal end of the shaft 250 extends through the vacuum pump 180 attached to the bottom end of the stem portion 134 of the pedestal 130. One of the actuators 170 is attached to the distal end of the shaft 250. The actuator 170 can move the shaft 250 through the vacuum pump 180 and through the stem portion 134 and the base portion 132 of the pedestal 130 to lift and lower the substrate 140. In FIG. 10. when lifted, the substrate 140 is held by the T-shaped end of the shaft 250. When lifted, the actuator 170 can also rotate the shaft 250 to rotate the substrate 140 relative to the optical array 150.

A conduit 252 is bored through the shaft 250. The conduit 252 and the shaft 250 are coaxial. The conduit 252 extends through the shaft 250 up to the T-shaped end of the shaft 250. The shaft 250 comprises a plurality of holes 254 bored radially through the T-shaped end of the shaft 250. Near the T-shaped end of the shaft 250, one end of the conduit 252 connects to the plurality of holes 254. A distal end of the conduit 252 extends out of the distal end of the shaft 250. The distal end of the conduit 252 is connected to one of the gas sources 104 through the valve 152 (shown in FIG. 1B). In FIG. 3B, when the shaft 250 lifts the substrate 140, a purge gas is supplied through the conduit 252. The purge gas flows through the conduit 252, flows out through the holes 254, and flows radially across and over the window 210 in the direction of the arrows shown to clean the window 210.

The stem portion 134 of the pedestal 130 further comprises a conduit 256 through which electrical connections (e.g., insulated wires or conductors) to the electrical elements in the base portion 132 of the pedestal 130 are routed. The distal ends of the electrical connections are connected to the controller 190 (shown in FIG. 1B). The conduit 256 is bored through and extends through the stem portion 134 of the pedestal 130. The conduit 256 extends into the base portion 132 of the pedestal 130 up to the inner annular region 204 of the optical array 150. The conduits 252, 256 and the shaft 250 are coaxial. A diameter of the conduit 256 is greater than the diameter of the shaft 250.

The stem portion 134 of the pedestal 130 further comprises a conduit 258. A diameter of the conduit 258 is greater than the diameter of the conduit 256 and less than the diameter of the stem portion 134 of the pedestal 130. The conduits 258, 252, 256 and the shaft 250 are coaxial. A first end of the conduit 258 is in fluid communication with the vacuum pump 180. A second end of the conduit 258 extends through the stem portion 134 of the pedestal 130 and into the base portion 132 of the pedestal 130. The second end of the conduit 258 extends into the base portion 132 of the pedestal 130 up to a point below the optical array 150. At the second end, the conduit 258 connects to a first set of conduits (or passages) 260 bored radially through the base portion 132 of the pedestal 130 below the optical array 150. The conduits 260 extend up to the OD of the base portion 132 of the pedestal 130. The conduits 260 are in fluid communication with the conduit 258.

A second set of conduits 262 is bored perpendicularly to the first set of conduits 260 through the base portion 132 of the pedestal 130. The conduits 262 extend from the conduits 260 through the optical array 150 and the window 210. The conduits 262 are in fluid communication with the conduits 260, 258. Accordingly, when the substrate 140 is to be clamped to the pedestal 130, the controller 190 activates the vacuum pump 180 and opens the valve 184 (shown in FIG. 1B) to create vacuum in the conduits 258, 260, 262. The vacuum in the conduits 258, 260, 262 clamps the substrate 140 to the pedestal 130. After the substrate is clamped to the pedestal 130, the controller 190 controls the optical array 150 to heat the substrate 140 as described above according to the process to be performed on the substrate 140.

In FIG. 10, when the substrate 140 needs to be rotated relative to the optical array 150, the controller 190 controls the vacuum pump 180 and the valve 184 such that the vacuum in the conduits 258, 260, 262 is reduced. The vacuum in the conduits 258, 260, 262 is sufficiently reduced to allow the shaft 250 to lift the substrate 140. The controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140.

When the substrate 140 is lifted, the controller 190 opens the valve 152 (shown in FIG. 1B) to allow the purge gas to flow through the conduit 252 and through the holes 254. The purge gas flows through the conduit 252 and the holes 254 radially over and across the window 210 as shown by arrows in FIG. 10. The flow of the purge gas over and across the window 210 removes any material that may be deposited on the window 210. The controller 190 controls the valves 152 and 184 (shown in FIG. 1B) such that the vacuum pump 180 continues suction though the conduits 258, 260, 262 and through the processing chamber 101 (shown in FIG. 1B). Accordingly, the material removed from the window 210 is evacuated from the processing chamber 101.

Subsequently, the actuator 170 lowers the shaft 250 to place the substrate 140 again on the pedestal 130. The substrate 140 is then vacuum clamped as described above. The optical array 150 again heats the substrate 140 as described above. The procedure is repeated as needed until the processing of the substrate 140 is complete.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above.” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments. be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An optical array arranged in a pedestal configured to deposit material on a substrate, the optical array comprising:
a plurality of optical elements arranged on a printed circuit board (PCB), wherein the optical elements are configured to emit light;
a window comprising an optically transparent material covering the optical elements arranged on the PCB; and
an array of pinholes disposed between the optical elements and the window, wherein the pinholes are vertically aligned with the optical elements to direct the light emitted by the optical elements through the window to heat the substrate.

2. The optical array of claim 1 further comprising lenses disposed between the optical elements and the pinholes, the lenses aligned with the optical elements and the pinholes to converge the light from the optical elements to the pinholes.

3. The optical array of claim 1 wherein the optical elements comprise lenses to converge the light from the optical elements to the pinholes.

4. The optical array of claim 1 wherein the array of pinholes comprises a metallic or dielectric material.

5. The optical array of claim 1 wherein the array of pinholes is integrated with the window in a monolithic assembly.

6. The optical array of claim 1 wherein the array of pinholes is coated with a reflective material on a side facing the window, the reflective material not covering the pinholes.

7. The optical array of claim 1 wherein the array of pinholes is coated with an antireflective material on a side facing the optical elements.

8. The optical array of claim 1 wherein the window is coated with:
an antireflective material on a side facing the optical elements; and
a material that is antireflective for wavelengths of the light emitted by the optical elements and that is reflective for infrared wavelengths on a side facing the substrate.

9. The optical array of claim 1 wherein the window is coated with an antireflective material on a side facing the optical elements, the window further comprising a reflective material coated on the antireflective material, the reflective material comprising a metal film and the pinholes.

10. The optical array of claim 1 wherein the optical elements comprise light emitting diodes.

11. The optical array of claim 1 wherein the optical elements comprise light emitting diodes configured to emit light having wavelengths between 530 nm and 1000 nm.

12. The optical array of claim 1 wherein the optical array is circular and wherein the optical elements and the pinholes are arranged in concentric circles from an inner diameter to an outer diameter of the optical array.

13. The optical array of claim 1 further comprising:
lenses disposed between the optical elements and the pinholes;
wherein the optical array is circular;
wherein the optical elements, the pinholes, and the lenses are arranged in concentric circles from an inner diameter to an outer diameter of the optical array; and
wherein the lenses are aligned with the optical elements and the pinholes to converge the light from the optical elements to the pinholes.

14. The optical array of claim 1 wherein the pinholes are cylindrical.

15. The optical array of claim 1 wherein the pinholes are conical with bases facing the optical elements.

16. The optical array of claim 1 wherein the PCB further comprises one or more driver circuits configured to control power supply to the optical elements.

17. The optical array of claim 1 wherein the PCB further comprises one or more driver circuits configured to control operation of selected ones of the optical elements.

18. The optical array of claim 1 wherein the PCB further comprises driver circuits configured to control the light emitted by the optical elements, wherein the driver circuits are arranged on the same side of the PCB as the optical elements, on an opposite side of the PCB, or on both sides of the PCB.

19. The optical array of claim 1 further comprising a heat sink attached to a side of the PCB opposite to a side on which the optical elements are arranged on the PCB.

20. The optical array of claim 1 wherein the window is sealingly attached to the PCB.

21. A system comprising:
the optical array of claim 1; and
the pedestal, the pedestal comprising:
a stem portion; and
a base portion mounted to the stem portion,
wherein the optical array is disposed in the base portion of the pedestal.

22. The system of claim 21 wherein the base portion and the optical array are coplanar.

23. The system of claim 21 wherein the base portion and the optical array are circular and wherein an outer diameter of the optical array is less than or equal to an outer diameter of the base portion.

24. The system of claim 21 wherein the base portion and the optical array are circular and wherein an outer diameter of the array is less than or equal to an outer diameter of the substrate.

25. The system of claim 21 wherein the base portion and the optical array are circular and wherein an outer diameter of the array is at least equal to an outer diameter of the substrate.

26. The system of claim 21 wherein the pedestal further comprises:
a shaft disposed through centers of the stem portion, the base portion, and the array; and
an actuator coupled to the shaft and configured to move the substrate relative to the pedestal.

27. The system of claim 21 wherein the pedestal further comprises:
a shaft disposed through centers of the stem portion, the base portion, and the array; and
an actuator coupled to the shaft and configured to move the substrate perpendicularly relative to a plane in which the base portion lies.

28. The system of claim 21 wherein the pedestal further comprises:
a shaft disposed through centers of the stem portion, the base portion, and the array; and
an actuator coupled to the shaft and configured to rotate the substrate relative to the base portion.

29. The system of claim 21 wherein the pedestal further comprises:
a shaft disposed through centers of the stem portion, the base portion, and the array, wherein the shaft comprises a conduit to receive a gas and a plurality of holes in fluid communication with the conduit near a first end of the shaft proximate to the array; and
an actuator coupled to a second end of the shaft and configured move the substrate perpendicularly relative to a plane in which the base portion lies,
wherein the plurality of holes supply the gas radially over the window when the shaft is raised above the array.

30. The system of claim 21 wherein the array of pinholes is connected to a ground potential.
